(19) United States
(12) Patent Application Publication
(10) Pub. No.: US 2024/0263349 A1
(43) Pub. Date: Aug. 8, 2024

(54) PHASE-CONTROLLABLE SYNTHESIS OF TRANSITION METAL DICHALCOGENIDE MONOLAYER CRYSTALS

(71) Applicant: City University of Hong Kong, Hong Kong (HK)

(72) Inventors: Hua ZHANG, Hong Kong (HK); Wei ZHAI, Hong Kong (HK); Yongji WANG, Hong Kong (HK)

(21) Appl. No.: 18/331,209

(22) Filed: Jun. 8, 2023

Related U.S. Application Data
(60) Provisional application No. 63/482,797, filed on Feb. 2, 2023.

(51) Int. Cl. C30B 25/16; C30B 25/10; C30B 25/18; C30B 29/46

(52) U.S. Cl. CPC C30B 25/16; C30B 25/10; C30B 25/18; C30B 29/46

(57) ABSTRACT

The present invention provides a general salt-assisted chemical vapour deposition method for phase-controllable synthesis of 1T′ and 2H-phase transition metal dichalcogenide (TMD) monolayer crystals. The method comprises: mixing a transition metal compound powder and a salt powder to form a precursor; placing a substrate on top of the precursor; placing the precursor and the substrate at a center position in a chemical vapour deposition (CVD) furnace; placing a chalcogen powder at an upstream position relative to the precursor along a gas-flow direction in the CVD furnace; heating up the CVD furnace to a growth temperature within the heat-up time; keeping the CVD furnace at the growth temperature for a growth time under a mixed gas flow of H₂ and Ar. The optical and electrical characterizations reveal the phase-dependent in-plane isotropy and anisotropy of the as-synthesized 2H and 1T′-phase crystals. The 1T′-TMD monolayer crystals demonstrate much-improved phase transition temperatures.

### CROSS-REFERENCE TO RELATED APPLICATIONS

The present application claims priority to the U.S. Provisional Patent Application No. 63/482,797 filed on Feb. 2, 2023. The disclosure of which is incorporated herein by reference in its entirety.

### FIELD OF THE INVENTION

The present invention generally relates to synthesis of transition metal dichalcogenide (TMD) monolayer crystals. More specifically, the present invention relates to a general salt-assisted chemical vapour deposition (CVD) method for phase-controllable synthesis of transition metal dichalcogenide monolayer crystals.

### BACKGROUND OF THE INVENTION

Two-dimensional (2D) TMDs have gained intensive research interest owing to their intriguing physicochemical properties, including valley polarization, spin Hall effect, superconductivity, and ferroelectricity. As a group of materials existing in polymorphs, TMDs with different phases can demonstrate distinct physiochemical properties for various applications.

Several strategies have been employed to explore the phase-controllable synthesis of group VIB TMD monolayer crystals, such as the potassium-assisted method, temperature control, colloidal synthesis, molecular beam epitaxy, and the gas-source method. However, existing methods are not universal for the phase-controllable synthesis of a wide range of TMD monolayer crystals. The phase-controllable growth of TMD monolayers remains challenging because high synthetic temperatures can easily transform the unconventional phases back to thermodynamically stable phases. The lateral sizes of the synthesized monolayer crystals synthesized by conventional CVD methods are mainly limited to 10 μm, severely hindering the exploration of phase-dependent properties and applications. Therefore, a general method for phase-controllable synthesis of large-size TMD monolayer crystals with thermodynamically metastable phases, such as 1T′ and 2H phases, is highly desirable.

### SUMMARY OF THE INVENTION

In accordance with a first aspect of the present disclosure, a general method for phase-controllable synthesis of a TMD monolayer crystal is provided. The method comprises: mixing a transition metal compound powder and a salt powder to form a precursor; placing a substrate on top of the precursor; placing the precursor and the substrate at a center position in a chemical vapour deposition (CVD) furnace; placing a chalcogen powder at an upstream position relative to the precursor along a gas-flow direction in the CVD furnace; heating up the CVD furnace to a growth temperature within the heat-up time; keeping the CVD furnace at the growth temperature for a growth time under a mixed gas flow of H₂ and Ar.

In accordance with a further aspect, the first temperature ranges for chalcogenides from 250 to 300° C.; the second temperature ranges for the mixture of salt and transition metal oxides/sulfides from 825 to 875° C.; the heating time is less than 10 minutes; the growth time ranges from 2 to 10 minutes; the heat-up time ranges from 5 to 15 minutes; and the cooling time ranges is less than 10 minutes.

In accordance with a further aspect, the substrate is a fluorophlogopite mica substrate or a sapphire substrate.

In accordance with a further aspect, the salt powder is a potassium carbonate (K₂CO₃) powder, a potassium oxalate (K₂C₂O₄) powder, a potassium sulphate (K₂SO₄) powder, a sodium carbonate (Na₂CO₃) powder, a sodium oxalate (Na₂C₂O₄) power or a sodium sulphate (Na₂SO₄) power.

In accordance with a further aspect, the substrate is placed exactly on top of the precursor such that the TMD monolayer crystal grown on the substrate has a 1T′ phase.

In accordance with a further aspect, the substrate is placed away from the precursor for a diffusion distance ranging from 1 to 3 cm along the gas-flow direction such that the TMD monolayer crystal grown on the substrate has a 2H phase.

In accordance with a further aspect, the transition metal compound powder is a molybdenum compound powder and the chalcogen powder is a sulfur powder such that the TMD monolayer crystal grown on the substrate is a molybdenum disulfide monolayer crystal.

In accordance with a further aspect, the molybdenum compound powder is a molybdenum trioxide powder.

In accordance with a further aspect, the molybdenum compound powder is a molybdenum disulfide powder.

In accordance with a further aspect, the transition metal compound powder is a tungsten compound powder and the chalcogen powder is a sulfur powder such that the TMD monolayer crystal grown on the substrate is a tungsten disulfide monolayer crystal.

In accordance with a further aspect, the tungsten compound powder is a tungsten trioxide powder.

In accordance with a further aspect, the tungsten compound powder is a tungsten disulfide powder.

In accordance with a further aspect, the transition metal compound powder is a molybdenum compound powder and the chalcogen powder is a selenium powder such that the TMD monolayer crystal grown on the substrate is a molybdenum diselenide monolayer crystal.

In accordance with a further aspect, the molybdenum compound powder is a molybdenum trioxide powder.

In accordance with a further aspect, the molybdenum compound powder is a molybdenum diselenide powder.

In accordance with a further aspect, the transition metal compound powder is a tungsten compound powder and the chalcogen powder is a selenium powder such that the TMD monolayer crystal grown on the substrate is a tungsten diselenide monolayer crystal.

In accordance with a further aspect, the tungsten compound powder is a tungsten trioxide powder.

In accordance with a further aspect, the tungsten compound powder is a tungsten diselenide powder.

The present invention provides a general salt-assisted CVD method for phase-controllable synthesis of 2H and 1T′-phase group VIB TMDs, i.e., MoS₂, WS₂, MoSe₂, WSe₂, MoS₂ₓSe₂₍₁₋ₓ₎, WS₂ₓSe₂₍₁₋ₓ₎, and various doped MoS₂ (i.e., Cr-doped, Nb-doped and Re-doped MoS₂) monolayer crystals. The as-synthesized crystals are single crystalline with high phase purity which is evident in the comprehensive characterizations.

The optical and electrical characterizations reveal the phase-dependent in-plane isotropy and anisotropy of 2H and 1T′-phase crystals. Compared to 1T′-TMD bulky crystals with phase transition temperatures ranging from 60° C. to 160° C. which has limiting practical application in (opto)electronics, the 1T′-TMD monolayer crystals demonstrate much-improved phase transition temperatures ranging from 300° C. to 500° C., paving the road of metastable 1T′-TMD crystals for practical (opto)electronics.

In accordance with a second aspect of the present disclosure, the present invention provides a rectifier employing a 2D homojunction Schottky diode based on a van der Waals integrated 2D metal-2D semiconductor homojunction, wherein the homojunction includes: a metal part formed of a 1T-TMD monolayer crystal having a 1T′ phase; and a semiconductor part formed of a 2H-TMD monolayer crystal having a 2H phase.

The van der Waals integrated 2D metal-2D semiconductor homojunction can avoid the formation of the surface states and the rectifier provided by the present invention demonstrates a rectifying ratio of as high as over 10⁵, indicating the great potential for future electronics.

### BRIEF DESCRIPTION OF THE DRAWINGS

Embodiments of the invention are described in more details hereinafter with reference to the drawings, in which:

FIG. 1 shows a general schematic diagram of a CVD method for phase-controllable synthesis of 1T′ and 2H-TMD monolayer crystals according to some embodiments of the present invention;

FIG. 2 shows more details on synthesis of 1T′-TMD and 2H-TMD respectively;

FIGS. 3A and 3B show an optical image and an atomically resolved filtered high-angle annular dark-field scanning transmission electron microscopy (HAADF-STEM) image of the 1T′-MoS₂ monolayer crystal, respectively; inset of FIG. 3B shows selected area electron diffraction (SAED) pattern of the 1T′-MoS₂ monolayer crystal;

FIGS. 4A and 4B show an optical image and an atomically resolved filtered HAADF-STEM image of the 2H—MoS₂ monolayer crystal, respectively; inset of FIG. 4B shows SAED pattern of the 2H—MoS₂ monolayer crystal;

FIGS. 5A and 5B show Raman spectra the 1T′-MoS₂ and 2H—MoS₂ monolayer crystals, respectively;

FIGS. 6A and 6B show photoluminescence (PL) spectra of the 1T′-MoS₂and 2H—MoS₂ monolayer crystals, respectively;

FIGS. 7A and 7B show Raman mapping images of the 1T′-MoS₂and 2H—MoS₂ monolayer crystals, respectively;

FIGS. 8A and 8B show atomic force microscope (AFM) images of the 1T′-MoS₂ and 2H—MoS₂ monolayer crystals, respectively;

FIGS. 9A to 9C show X-ray photoelectron spectroscopy (XPS) spectra for the Mo 3d (FIG. 9A), Mo S2p (FIG. 9B) and Mo K 2p (FIG. 9C) orbits of the 1T′-MoS₂ and 2H—MoS₂ monolayer crystals, respectively;

FIG. 10 shows Ex-situ variable-temperature Raman spectra of the 1T′-MoS₂ monolayer crystals after annealed at room temperature (room temperature ˜25° C.), 50° C., 100° C., 150° C., 200° C., 250° C., 300° C., 350° C., and 400° C. for 10 min, respectively;

FIG. 11 shows PL spectra of 1T′-MoS₂ monolayer crystals before phase transition and after phase transition annealed at 400° C.;

FIGS. 12A and 12B show optical image and Raman spectrum of the as-synthesized 1T′-MoS₂ crystal synthesized on a sapphire substrate, respectively;

FIGS. 13A and 13B show an optical image and an atomically resolved filtered HAADF-STEM image of the 1T′-WS₂ monolayer crystal, respectively; inset of FIG. 13B shows SAED pattern of the 1T′-WS₂ monolayer crystal;

FIGS. 14A and 14B show an optical image and an atomically resolved filtered HAADF-STEM image of the 2H—WS₂ monolayer crystal, respectively; inset of FIG. 14B shows SAED pattern of the 2H—WS₂ monolayer crystal;

FIGS. 15A and 15B show AFM images of the 1T′-WS₂ and 2H—WS₂ monolayer crystals, respectively;

FIGS. 16A and 16B show Raman spectra the 1T′-WS₂ and 2H—WS₂ monolayer crystals, respectively;

FIGS. 17A and 17B show PL spectra of the 1T′-WS₂ and 2H—WS₂ monolayer crystals, respectively;

FIGS. 18A and 18B show Raman mapping images of the 1T′-WS₂ and 2H—WS₂ monolayer crystals, respectively;

FIGS. 19A to 19C show the XPS spectra for the W 4f_{5/2}and W 4f_{7/2} orbits (FIG. 19A), W S 2p_{1/2} and W S 4p_{3/2} orbits (FIG. 19B), the W K⁺ orbits (FIG. 19C) of the 1T′-WS₂ and 2H—WS₂ monolayer crystals, respectively;

FIG. 20 shows Ex-situ variable-temperature Raman spectra of the 1T′-WS₂ monolayer crystals after annealed at room temperature (RT ˜25° C.), 50° C., 100° C., 150° C., 200° C., 250° C., 300° C., 350° C., 400° C., 450° C. and 500° C. for 10 min, respectively;

FIGS. 21A and 21B show optical images of the 1T′-MoSe₂ and 2H—MoSe₂ monolayer crystals, respectively;

FIGS. 22A and 22B show Raman mapping images of the 1T′-MoSe₂ and 2H—MoSe₂ monolayer crystals, respectively;

FIG. 23 shows Raman spectra of the 1T′-MoSe₂ and 2H—MoSe₂ monolayer crystals;

FIG. 24 shows PL spectra of the 1T′-MoSe₂ and 2H—MoSe₂ monolayer crystals;

FIG. 25 shows Ex-situ variable-temperature Raman spectra of the 1T′-MoSe₂ monolayer crystals after annealed at room temperature (RT ˜25° C.), 50° C., 100° C., 150° C., 200° C., 250° C., 300° C., 350° C., and 400° C. for 10 min, respectively;

FIGS. 26A and 26B show optical images of the 1T′-WSe₂ and 2H—WSe₂ monolayer crystals respectively;

FIGS. 27A and 27B show Raman mapping images of 1T′-WSe₂ and 2H—WSe₂ monolayer crystals respectively. FIG. 28 shows Raman spectra of the 1T′-WSe₂ and 2H—WSe₂ monolayer crystals;

FIG. 29 shows PL spectra of the 1T′-WSe₂ and 2H—WSe₂ monolayer crystals;

FIG. 30 shows Ex-situ variable-temperature Raman spectra of the 1T′-WSe₂ monolayer crystals after annealed at room temperature (RT ˜25° C.), 50° C., 100° C., 150° C., 200° C., 250° C., 300° C., 350° C., 400° C., 450° C., and 500° C. for 10 min, respectively;

FIG. 31A shows high-resolution transmission electron microscopy (HR-TEM) image of 1T′-MoS₂ monolayer crystals and FIG. 31B shows the fast Fourier transform (FFT) patterns of the image of FIG. 31A;

FIGS. 32A and 32B show Raman intensity mapping and angle-dependent Raman intensities of the 1T′-MoS₂ monolayer crystal, respectively;

FIGS. 33A and 33B show Raman intensity mapping and angle-dependent Raman intensities of the 1T′-WS₂ monolayer crystal, respectively;

FIG. 34 shows Raman intensity mapping of the 1T′-MoSe₂ monolayer crystal;

FIG. 35 shows Raman intensity mapping of the 1T′-WSe₂ monolayer crystal;

FIGS. 36A and 36B show Raman intensity mapping and angle-dependent Raman intensities of the 2H—MoS₂ monolayer crystal, respectively;

FIGS. 37A and 37B show Raman intensity mapping and angle-dependent Raman intensities of the 2H—WS₂ monolayer crystal, respectively;

FIG. 38 shows Raman intensity mapping of the 2H—MoSe₂ monolayer crystal;

FIG. 39 shows Raman intensity mapping of the 2H—WSe₂ monolayer crystal;

FIG. 40A shows an optical image of a device fabricated with a 1T′-MoS₂ monolayer crystal with twelve evenly spaced Cr/Au electrodes; FIG. 40B shows I_{ds}-V_{ds} curves of the device of FIG. 40A;

FIG. 41A shows an optical image of a device fabricated with a 2H—MoS₂ monolayer crystal with twelve evenly spaced Cr/Au electrodes; FIG. 41B shows I_{ds}-V_{ds} curves of the device of FIG. 41A;

FIG. 42 shows an output curve of the device fabricated with a 1T′-MoS₂ monolayer crystal;

FIG. 43 shows a transfer curve of the device fabricated with a 1T′-MoS₂ monolayer crystal;

FIG. 44 shows an output curve of the device fabricated with a 2H—MoS₂ monolayer crystal;

FIG. 45 shows a transfer curve of the device fabricated with a 2H—MoS₂ monolayer crystal;

FIGS. 46A and 46B shows schematic illustration of interfaces of evaporated 3D metal-2D semiconductors (FIG. 46A) and 2D metal-2D semiconductors (FIG. 46B), respectively.

FIG. 47 shows schematic diagram of a Schottky diode fabricated with a van der Waals integrated 1T′-MoS₂-2H—MoS₂ 2D homojunction;

FIG. 48 shows an optimal image of the Schottky diode of FIG. 47;

FIG. 49A and 49B show band structure diagrams of the van der Waals integrated 1T′-MoS₂-2H—MoS₂ homojunction at zero and forward biased voltages, respectively;

FIGS. 50A and 50B show schematic illustration of the band structures of the 1T′-MoS₂-2H—MoS₂ 2D homojunction Schottky diode and the Pd-2H—MoS₂ Schottky diode, respectively;

FIG. 51 shows rectifying ratios of diodes fabricated with Pd-2H—MoS₂ and 1T′-MoS₂-2H—MoS₂ at different gate voltages, respectively.

### DETAILED DESCRIPTION

In the following description, embodiments of the present invention are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

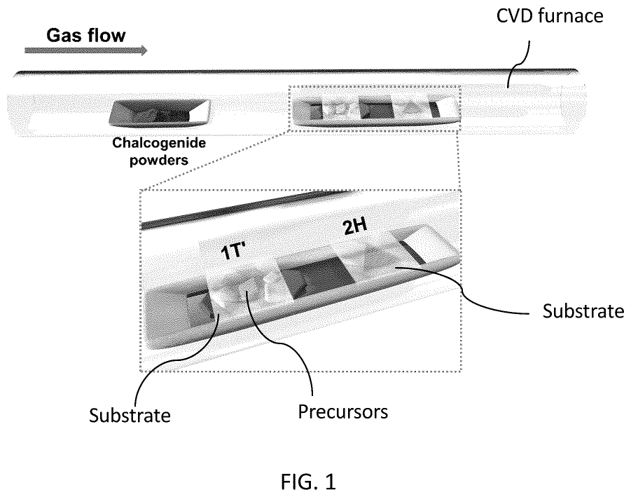

In accordance with one aspect of the present invention, a general and ultrafast salt-assisted CVD method is provided for phase-controllable synthesis of 1T′ and 2H-TMD monolayer crystals. The method adopts a one-pot synthesis strategy as illustrated in FIG. 1. As shown, a precursor, which is prepared by mixing a transition metal compound powders and a salt powder, is loaded in a quartz crucible. Then, a substrate is placed on top of the precursor. The precursor and the substrate are then place at a center position of a CVD furnace. Next, a chalcogen is placed at an upstream position relative to the precursor along a gas-flow direction in the CVD furnace. After filling up the DVD furnace with Ar gas, the CVD furnace is heated up to a first growth temperature within a first heat-up time and kept at the first growth temperature for a first growth time under a gas flow of Ar. Then, the CVD furnace is heated up to a second growth temperature within a second heat-up time and kept at the second growth temperature for a second growth time under a mixed gas flow of H₂ and Ar to grow the TMD monolayer crystal. Finally, the substrate grown with the TMD monolayer crystal is cooled down rapidly within a cooling time.

The salt powder may be, but not limited to, a potassium carbonate (K₂CO₃) powder, a potassium oxalate (K₂C₂O₄) powder, a potassium sulphate (K₂SO₄) powder, a sodium carbonate (Na₂CO₃) powder, a sodium oxalate (Na₂C₂O₄) power or a sodium sulphate (Na₂SO₄) power.

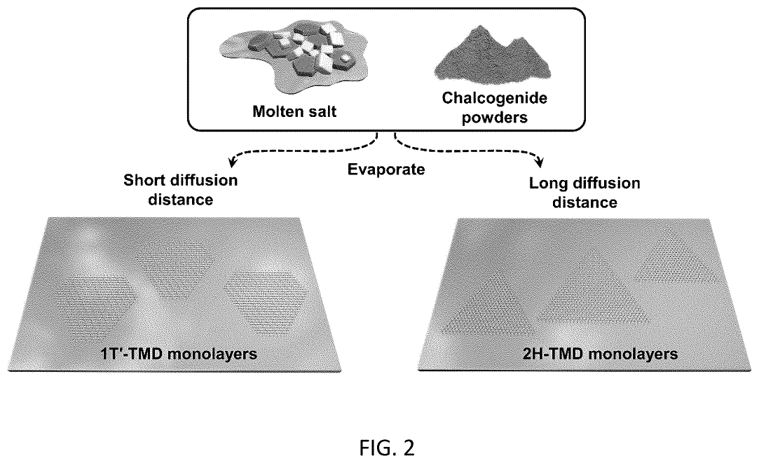

Referring to FIG. 2, the phase-controllable synthesis of TMD monolayer crystals was realized by adjusting the diffusion distance between the precursor and the substrate. Specifically, 1T′-TMD monolayer crystals can be grown by placing the substrate exactly on the top of the precursor (i.e., having a short diffusion distance) and heating the precursors at 800-850° C. under a mixed gas flow of H₂ and Ar with a volumetric flow rate ratio of H₂/Ar ranging from ⅕ to ⅔. On the other hand, 2H-TMD monolayer crystals can be obtained under similar synthetic conditions, except that the mica substrate was placed 2 cm from the precursor along the gas flow direction (i.e., having a long diffusion distance). Through the provided method, a series of 1T′ and 2H-TMD monolayer crystals, including but not limited to, 1T′-MoS₂, 2H—MoS₂, 1T′-WS₂, 2H—WS₂, 1T′-MoSe₂, 2H—MoSe₂ , 1T′-WSe₂, and 2H—WSe₂ monolayer crystals are synthesized.

In some embodiments, 1T′-TMD monolayer crystals and 2H-TMD monolayer crystals may be grown simultaneously in the same CVD furnace by placing a first substrate exactly on top of the precursor for 1T′-TMD growth and a second substrate 2 cm from the precursor along the gas flow direction for 2H-TMD growth.

### Synthesis of 1T′-MoS₂ Monolayer Crystal

In one embodiment, 1.0 mmol of MoO₃ powders (or MoS₂ powders) and 1.2 mmol of K₂CO₃ powders were grounded for 30 min in an agate mortar to obtain a precursor. 10 mg of the obtained precursor was transferred to a quartz crucible, in which one newly exfoliated fluorophlogopite mica substrate was exactly covered on the top of the mixture. The quartz crucible was then placed at the center of CVD furnace (e.g., a tube CVD furnace with an inner diameter of 2.0 cm). Another crucible boat containing 500 mg sulfur powder was placed at an upstream (upwind) position with a temperature of ˜250° C. relative to the precursor along a gas-flow direction in the CVD furnace. Then the CVD furnace was purged with a mixed H₂/Ar (10 s.c.c.m, standard cubic centimeter per minute/40 s.c.c.m) gas for 15 min, heated up to 850° C. within 10 min and kept at 850° C. for 6 min. After the reaction, the substrate was rapidly moved out of the furnace heating zone and cooled down to room temperature within 10 min. Then, the substrate was washed with deionized (DI) water to remove the adsorbed salt.

### Synthesis of 2H—MoS₂ Monolayer Crystal

The synthetic conditions for 2H—MoS₂ monolayer crystal were similar to those for 1T′-MoS₂ monolayer crystal except that the fluorophlogopite mica substrate was placed 2 cm from the precursor along the gas flow direction for 1T′-MoS₂ growth.

### Synthesis of 1T′-WS₂ Monolayer Crystal

In one embodiment, 1.0 mmol of WO₃powders (or WS₂powders) and 1.3 mmol of K₂CO₃ powders were grounded for 30 min in an agate mortar to obtain a precursor. 10 mg of the obtained precursor was transferred to a quartz crucible, in which one newly exfoliated fluorophlogopite mica substrate was exactly covered on the top of the precursor. The quartz crucible was then placed at the center of a CVD furnace (e.g., a tube CVD furnace with an inner diameter of 2.0 cm). Another crucible boat containing 500 mg sulfur powder was placed at an upstream (upwind) position with a temperature of ˜250° C. relative to the precursor along a gas-flow direction in the CVD furnace. Then the furnace was purged with a mixed H₂/Ar (20 s.c.c.m/30 s.c.c.m) gas for 15 min, heated up to 820° C. within 10 min and kept at 820° C. for 6 min. After that, the substrate was rapidly moved out of the furnace heating zone and cooled down to room temperature within 10 min. Then, the substrate was washed with DI water to remove the adsorbed salt.

### Synthesis of 2H—WS₂ Monolayer Crystal

The synthetic conditions of 2H—WS₂ monolayer crystals were similar to those for 1T′-WS₂ monolayer crystals, except that the fluorophlogopite mica substrate was placed 2 cm from the precursor along the gas flow direction for 1T′-WS₂ growth.

### Synthesis of 1T′-MoSe₂ Monolayer Crystal

In one embodiment, 1.0 mmol of MoO₃ powders (or MoSe₂ powders) and 1.3 mmol of K₂CO₃ powders were grounded for 30 min in an agate mortar to obtain a precursor. 10 mg of the obtained precursor was transferred to a quartz crucible, in which one newly exfoliated fluorophlogopite mica substrate was exactly covered on the top of the mixture. The quartz crucible was then placed at the center of a CVD furnace (e.g., a tube CDV furnace with an inner diameter of 2.0 cm). Another crucible boat containing 500 mg selenium powder was placed at an upstream (upwind) position with a temperature of ˜300° C. relative to the precursor along a gas-flow direction in the CVD furnace. Then the furnace was purged with a mixed H₂/Ar (10 s.c.c.m/40 s.c.c.m) gas for 15 min, heated up to 850° C. within 10 min and kept at 850° C. for 6 min. After that, the substrate was rapidly moved out of the furnace heating zone and cooled down to room temperature within 10 min. Then, the substrate was washed with DI water to remove the adsorbed salt.

### Synthesis of 2H—MoSe₂ Monolayer Crystal

The synthetic conditions of 2H—MoSe₂ monolayer crystals were similar to those for 1T′-MoSe ₂ except that the fluorophlogopite mica substrate was placed 2 cm from the precursor along the gas flow direction for 1T′-MoSe₂ growth.

### Synthesis of 1T′-WSe₂ Monolayer Crystal

In one embodiment, 1.0 mmol of WO₃ powders (or WSe₂powders) and 1.3 mmol of K₂CO₃ powders were grounded for 30 min in an agate mortar to obtain a precursor. 10 mg of the obtained precursor was transferred to a quartz crucible, in which one newly exfoliated fluorophlogopite mica substrate was exactly covered on the top of the mixture. The quartz crucible was then placed at the center of a CVD furnace (e.g., a tube CVD furnace with an inner diameter of 2.0 cm). Another crucible boat containing 500 mg selenium powder was placed at an upstream (upwind) position with a temperature of ˜300° C. relative to the precursor along a gas-flow direction in the CVD furnace. Then the furnace was purged with a mixed H₂/Ar (10 s.c.c.m/40 s.c.c.m) gas for 15 min, heated up to 850° C. within 10 min and kept at 850° C. for 6 min. After that, the substrate was rapidly moved out of the furnace heating zone and cooled down to room temperature within 10 min. Then, the substrate was washed with DI water to remove the adsorbed salt.

### Synthesis of 2H—WSe₂ Monolayer Crystal

The synthetic conditions of 2H—WSe₂ monolayer crystals were similar to those for 1T′-WSe₂ except that the fluorophlogopite mica substrate was placed 2 cm from the precursor along the gas flow direction for 1T′-WSe₂ growth.

### Characterization of 1T′ and 2H—MoS₂ monolayer crystal

The as-synthesized 1T′ and 2H—MoS₂ monolayer crystals were first characterized by an optical microscope (OM).

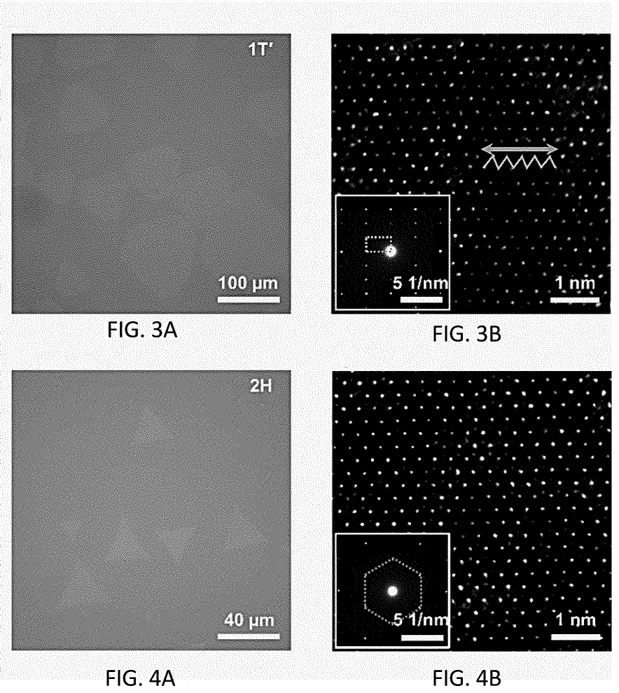

As shown in FIG. 3A, the synthesized 1T′-MoS₂ monolayer crystals demonstrate a hexagonal shape with lateral sizes of up to 140 μm. To further confirm the crystal phase, STEM was used to characterize the atomic arrangement of the synthesized monolayer crystals. As shown in FIG. 3B, the HAADF-STEM image clearly demonstrates that the as-synthesized monolayer crystals were 1T′-phase, which shows clear zigzag chains with a Mo-Mo distance of 2.8 Å. The SAED pattern of the synthesized 1T′-MoS₂ monolayer crystal (inset of FIG. 3B) also demonstrates a typical diffraction pattern of the 1T′ phase with a lower symmetrical 1×\sqrt{3} rectangular supercell compared to the 1T phase. In contrast, as shown in FIG. 4A, the synthesized 2H—MoS₂ monolayer crystal demonstrates a triangular shape, which is distinct from that of the 1T′-MoS₂ monolayer crystals. Its 2H phase is revealed by the atomically resolved HAADF-STEM image (FIG. 4B) and the SAED pattern (inset of FIG. 4B).

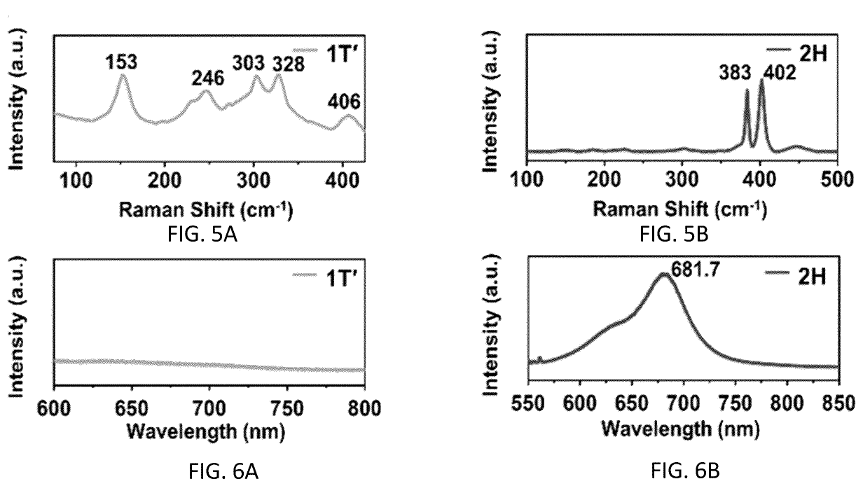

The different atomic arrangements in these two phases of MoS₂ can lead to distant Raman characteristic peaks. As shown in FIGS. 5A and 5B, Raman characterization of the as-synthesized 1T′-MoS₂ monolayer crystals shows a typical Raman spectrum with peaks located at 153 cm⁻¹, 246 cm⁻¹, 303 cm⁻¹, 328 cm⁻¹, 406 cm⁻¹ (FIG. 5A), which are different from the Raman spectrum of the 2H—MoS₂ monolayer crystals with peaks located at 383 cm⁻¹ and 401 cm⁻¹ (FIG. 5B).

As shown in FIGS. 6A and 6B, the PL spectra also demonstrate the bandgap structure difference between 1T′ and 2H—MoS₂ monolayer crystals. The vanishment of the optical bandgap in the as-synthesized 1T′-MoS₂ monolayer crystals (FIG. 6A) indicates that the crystals are metals. Differently, the as-synthesized 2H—MoS₂ monolayer crystals show a typically strong PL peak of 2H—MoS₂ monolayer crystals at ˜680 nm (FIG. 6B), indicating the as-synthesized 2H—MoS₂ crystals are monolayers with a direct bandgap of ˜1.8 eV²⁰.

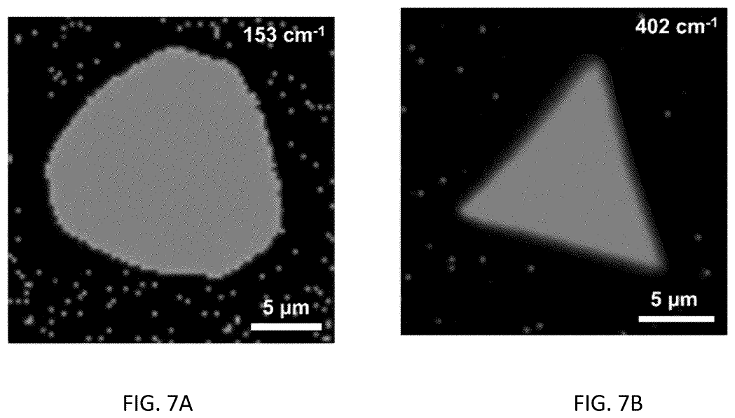

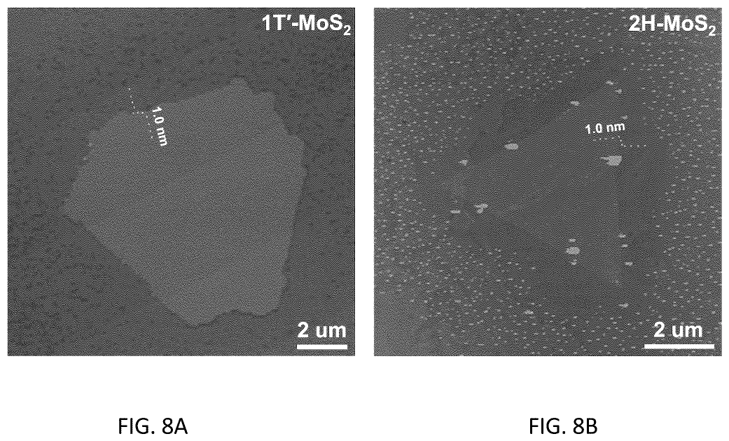

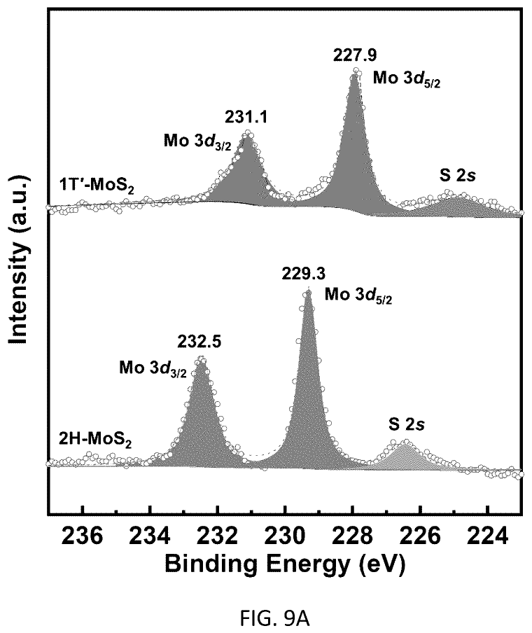

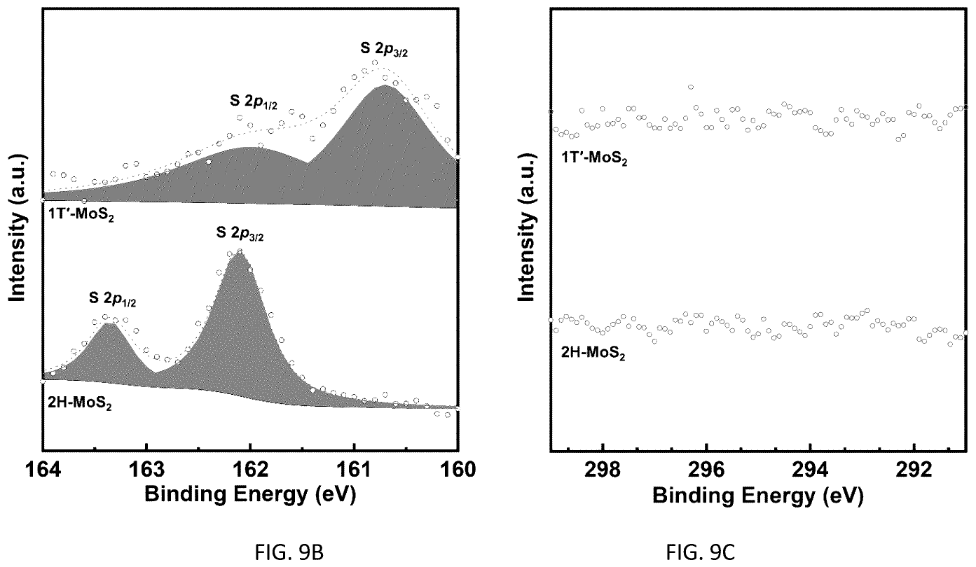

The Raman mapping images (FIGS. 7A and 7B) taken with the peaks at 153 cm⁻¹ (the strongest peak of 1T′-MoS₂) and 402 cm⁻¹ (A_{1g} mode of 2H—MoS₂) all show the good phase uniformity of the as-synthesized 1T′ and 2H—MoS₂ monolayer crystals, respectively. The AFM images (FIGS. 8A and 8B) further confirm that all the CVD-grown 1T′ and 2H—MoS₂ crystals are monolayers. The phase purity of the synthesized 1T′ and 2H—MoS₂ monolayers is further confirmed by XPS characterization (FIGS. 9A to 9C). Compared to 2H—MoS₂ monolayer crystals with two main Mo 3d peaks located at around 229.3 eV (Mo 3d_{5/2} orbit) and 232.5 eV (Mo 3d_{3/2} orbit), the 1T′-MoS₂ monolayer crystals show two shifted Mo 3d peaks at around 227.9eV (Mo 3d_{5/2} orbit) and 231.1 eV (Mo 3d_{3/2} orbit) in the XPS spectra (FIG. 9A). A similar shift was observed in the XPS spectra of the S 2s and 2p peaks (FIG. 9B). The binding energy peaks attributed to 2H—MoS₂ monolayer crystals were not detected in the 1T′-MoS₂ sample, indicating the high-phase purity of the synthesized monolayer crystals. In addition, no peak attributed to the K⁺ orbit was observed in the as-synthesized 1T′ and 2H—MoS₂ monolayer crystals (FIG. 9C), manifesting the high quality of the monolayer crystals.

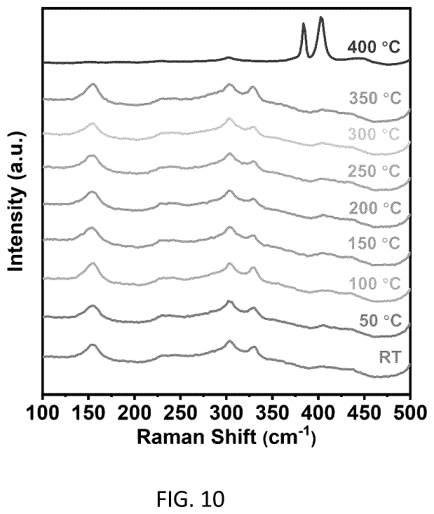

To further confirm the as-synthesized 1T′-MoS₂ monolayer crystals are metastable, ex-situ variable-temperature Raman spectroscopy was employed. As indicated in FIG. 10, the as-synthesized 1T′-MoS₂ monolayer crystals remain the pure 1T′ phase until 350° C. and show an improved thermodynamic stability compared to the as-synthesized 1T′-MoS₂ bulk crystals with a phase transition temperature of around 60° C. When the temperature was raised up to 400° C., the Raman spectra indicated that the phase of the as-synthesized 1T′-MoS₂ monolayer crystals had almost completely transformed from the 1T′ phase to the 2H phase.

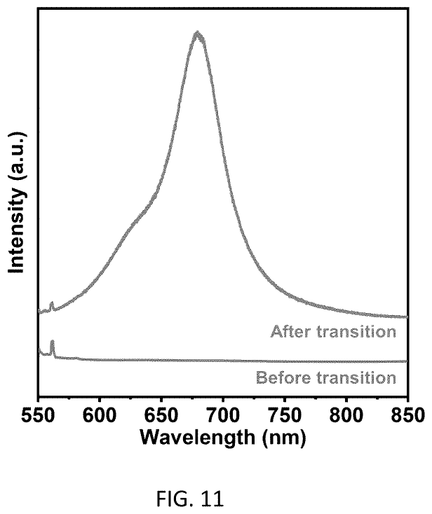

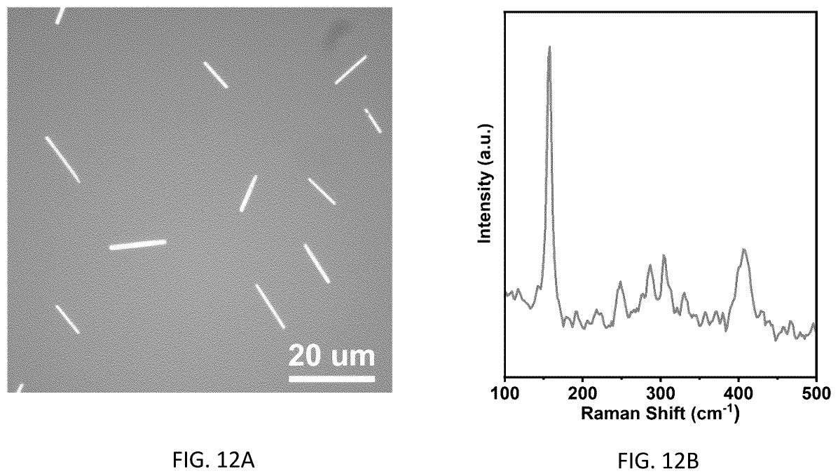

Consistent with the Raman spectra, the PL spectra (FIG. 11) also demonstrate a strong PL peak at ˜680 nm after annealing at 400° C. for 5 min, indicating the phase transition from the metallic 1T′ phase to the semiconducting 2H phase. The strong PL peak at ˜680 nm means that the 1T′-MoS₂ crystals annealed at 400° C. can transform into 2H—MoS₂ monolayers with a direct bandgap of ˜1.8 eV, indicating the crystals before phase transition are monolayers too. In addition, referring to FIGS. 12A and 12B, 1T′-MoS₂ can be grown not only on mica substrates but also on potassium-free sapphire substrates.

### Characterization of 1T′ and 2H—WS₂ monolayer crystal

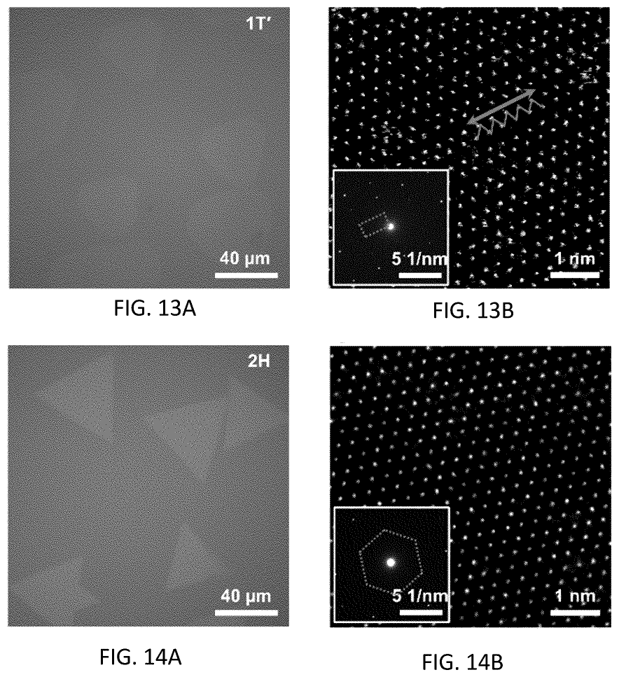

The optical image (FIG. 13A) demonstrates that the as-synthesized 1T′-WS₂ monolayer crystals have a hexagonal shape with a later size of up to 70 μm. The typical zigzag chains with a W-W distance of 2.8 Å in the HAADF-STEM image (FIG. 13B) clearly reflect that the as-synthesized WS₂ monolayer crystals have the 1T′ phase. The inset SAED pattern (inset of FIG. 13B) of the as-synthesized 1T′-WS₂ monolayer crystals also shows a typical diffraction pattern of the 1T′ phase. Compared to the hexagonal shape of 1T′-WS₂ monolayer crystals, the synthesized 2H—WS₂ monolayer crystals show a different triangular shape in the optical image (FIG. 14A). The atomically resolved HAADF-STEM image (FIG. 14B) and the SAED pattern (inset of FIG. 14B) all reveal the synthesized WS₂ has a good crystalline 2H phase.

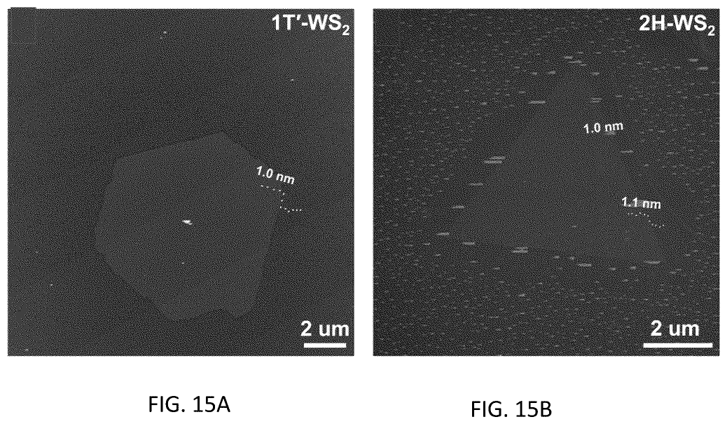

The thickness of the as-synthesized CVD-grown 1T′ and 2H—WS₂ crystals measured by AFM further confirms that both of them are monolayers (FIGS. 15A and 15B).

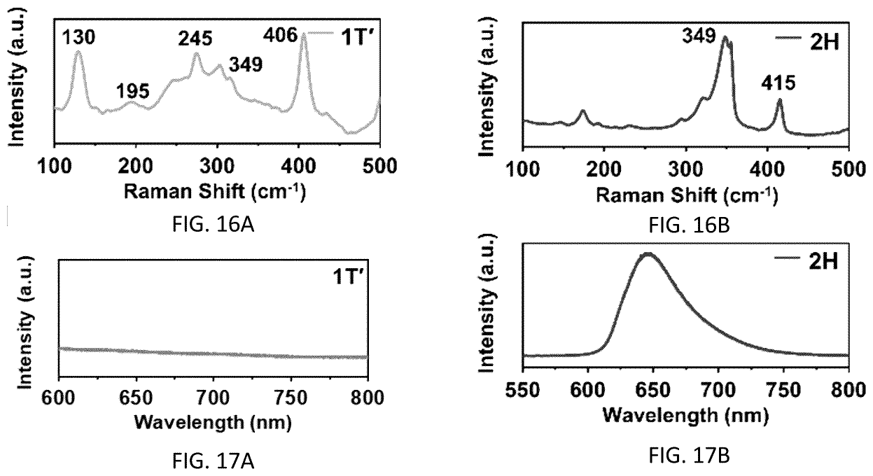

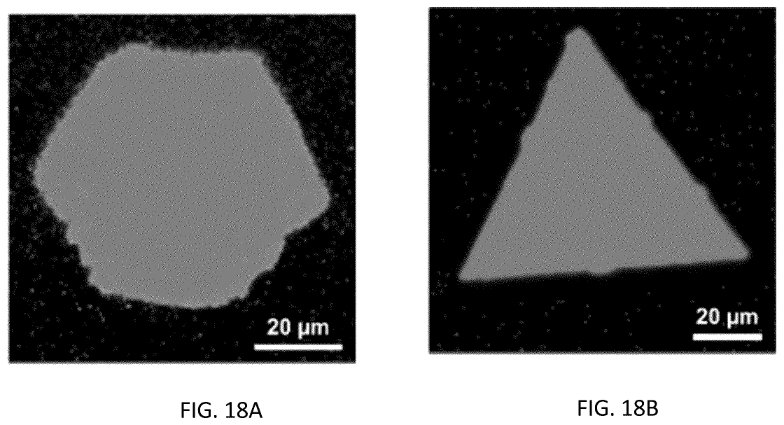

The phase difference was further reflected by the Raman and PL spectroscopy. Compared to the 2H—WS₂ monolayer crystals with two typical Raman peaks (FIG. 16B) at 349 cm⁻¹ and 415 cm⁻¹²², the as-synthesized 1T′-WS₂ monolayer crystals demonstrate much more Raman peaks (FIG. 16A) at 130 cm⁻¹, 195 cm⁻¹, 245 cm⁻¹, 275 cm⁻¹, 316 cm⁻¹ and 406 cm⁻¹ (21). The PL spectra further reflect the bandgap structure difference between 1T′ and 2H—WS₂. The absence of the optical bandgap in the PL spectrum (FIG. 17A) indicates the as-synthesized 1T′-WS₂ monolayer crystals are metals. In contrast, the PL spectrum of the as-synthesized 2H—WS₂ crystals (FIG. 17B) shows a semiconducting feature with a typical strong PL peak of ˜646 nm which indicates the crystals are monolayers with a direct bandgap of ˜1.92 eV. The Raman mapping images (FIGS. 18A and 18B) taken with the peaks at 130 cm⁻¹ of 1T′-WS₂ and 349 cm⁻¹ of 2H—WS₂ further indicate the good phase uniformity of the as-synthesized WS₂ monolayer crystals.

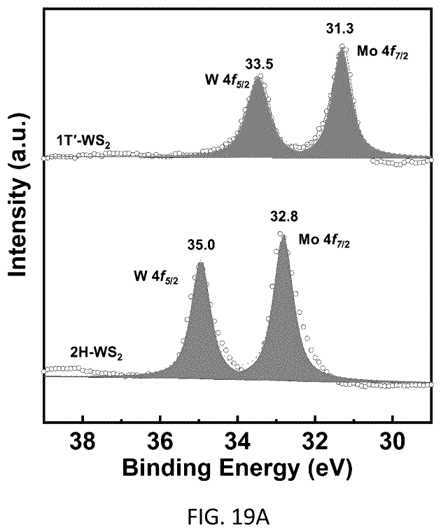

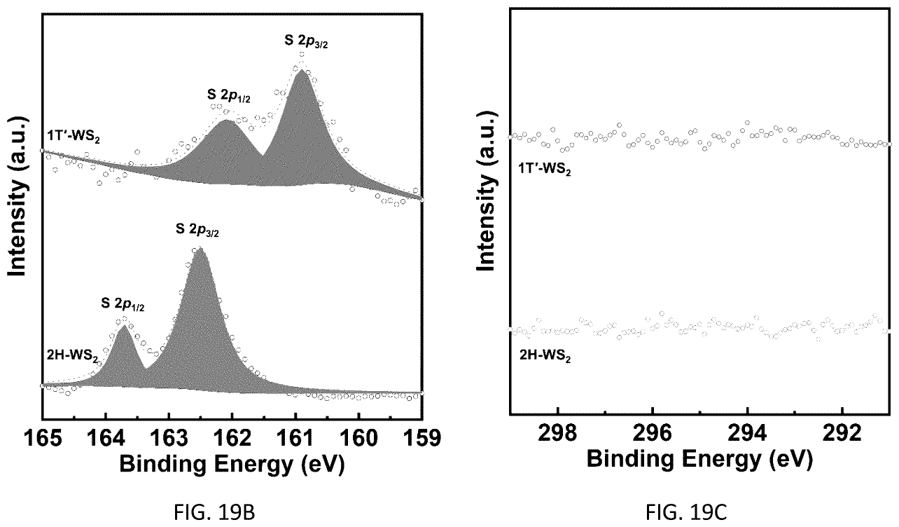

To further evaluate the high-phase purity of the as-synthesized 1T′ and 2H—WS₂ monolayer crystals, XPS measurements are employed on the as-synthesized WS₂ monolayer crystals (FIGS. 19A to 19C). Referring to FIG. 19A, a shift of ˜1.5 eV toward lower binding energies was observed in W 4f_{5/2} (33.5 eV) and W 4f_{7/2} (31.3 eV) peaks of 1T′-WS₂ monolayer crystals compared to W 4f_{5/2} (35.0 eV) and W 4f_{7/2} (32.8 eV) peaks of 2H—WS₂ monolayer crystals, indicating a lower valance state of the W element in the 1T′-WS₂ monolayer crystals. The binding energy peaks attributed to 2H—WS₂ monolayer crystals were not detected in the 1T′-WS₂ sample, indicating the high-phase purity of the as-synthesized 1T′-WS₂ monolayer crystals. The same shift was also observed in the XPS spectra of the S 2p orbit (FIG. 19B). In addition, no peak attributed to K⁺ was detected in the as-synthesized 1T′ and 2H—WS₂ monolayers (FIG. 19C), manifesting the high quality of the as-synthesized monolayer crystals.

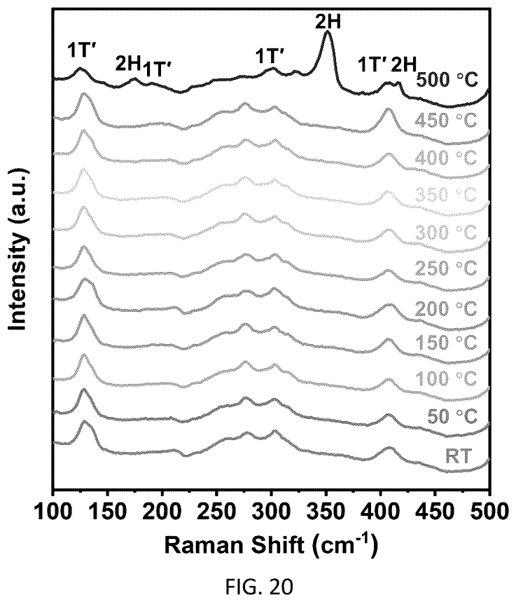

To further check the metastable character of the as-synthesized 1T′-WS₂ monolayer crystals, ex-situ variable-temperature Raman spectroscopy was employed (FIG. 20). Compared to the 1T′-WS₂ bulk crystals, the as-synthesized 1T′-WS₂ monolayer crystals can demonstrate much-improved thermodynamic stability, which can maintain the 1T′ phase until 450° C. When the annealing temperature approaches 500° C., the 1T′-WS₂ would partially transform into 2H—WS₂.

### Characterization of 1T′ and 2H—MoSe₂ Monolayer Crystals

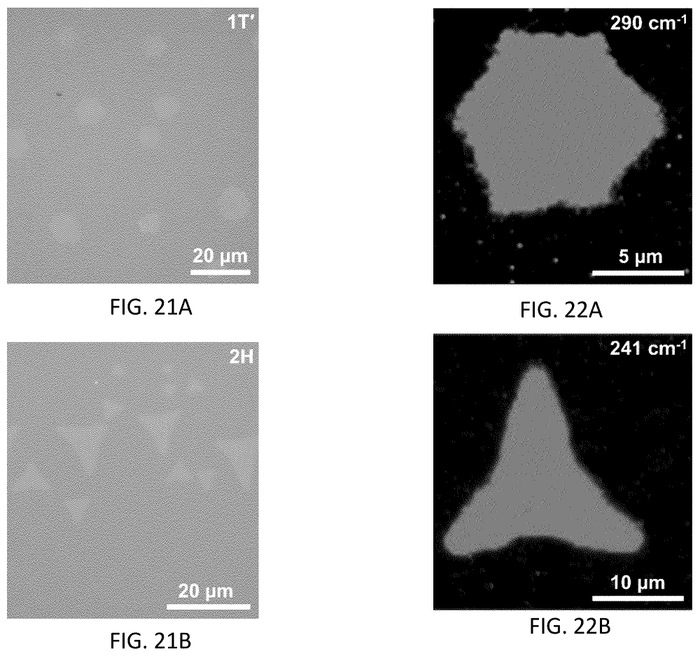

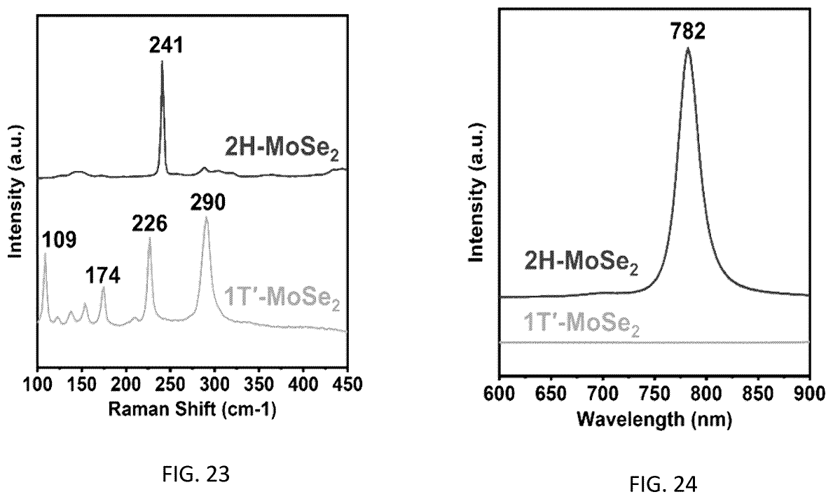

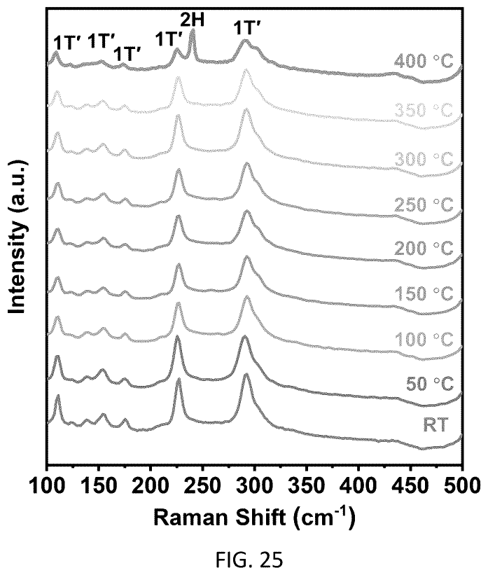

FIGS. 21A and 21B show optical images of the as-synthesized 1T′ and 2H—MoSe₂ monolayer crystals respectively. FIGS. 22A and 22B show Raman mapping images of the as-synthesized 1T′ and 2H—MoSe₂ monolayer crystals respectively. FIG. 23 shows Raman spectra of the as-synthesized 1T′ and 2H—MoSe₂ monolayer crystals. FIG. 24 shows PL spectra of the as-synthesized 1T′ and 2H—MoSe₂ monolayer crystals. The Ex-situ variable-temperature Raman spectra of the synthesized 1T′-MoSe₂ (FIG. 25) show much improved thermostabilities compared to those of bulk crystals.

### Characterization of 1T′ and 2H—WSe₂ Monolayer Crystals

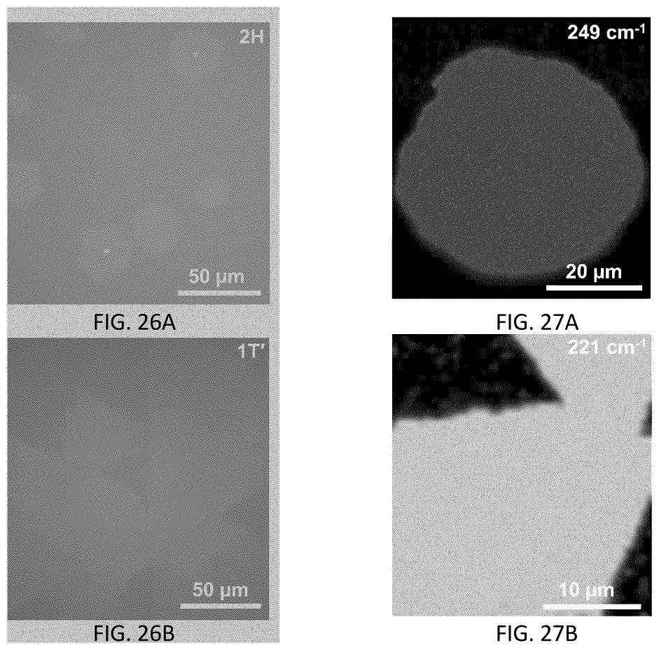

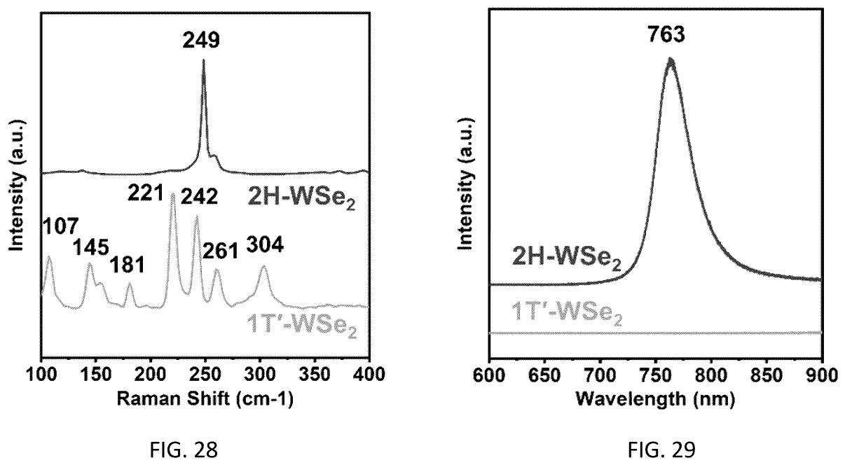

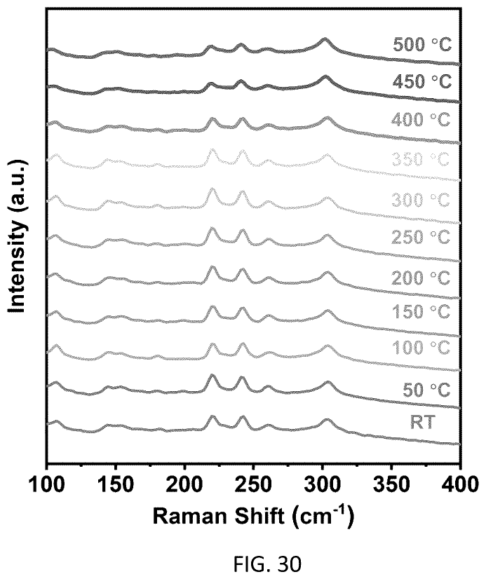

FIGS. 26A and 26B show optical images of the as-synthesized 1T′ and 2H—WSe₂ monolayer crystals respectively. FIGS. 27A and 27B show Raman mapping images of the as-synthesized 1T′ and 2H—WSe₂ monolayer crystals respectively. FIG. 28 shows Raman spectra of the as-synthesized 1T′ and 2H—WSe₂ monolayer crystals. FIG. 29 shows PL spectra of the as-synthesized 1T′ and 2H—WSe₂ monolayer crystals. The Ex-situ variable-temperature Raman spectra of the synthesized 1T′-WSe₂ (FIG. 30) show much improved thermostabilities compared to those of bulk crystals.

### Phase-Dependent Structural and Electrical Properties

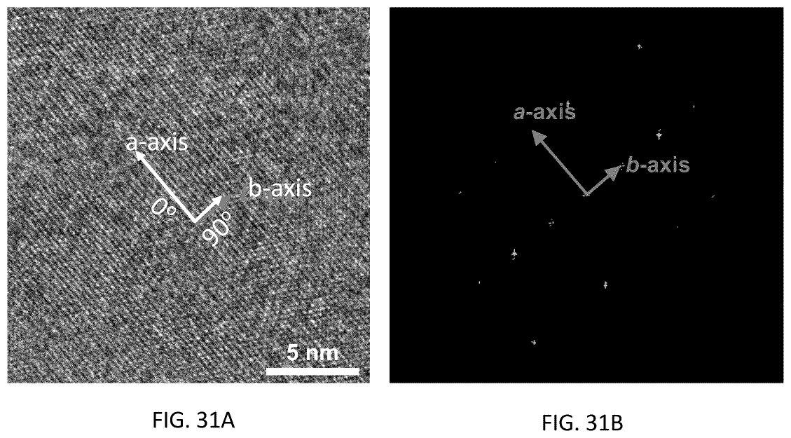

To further explore the phase-dependent physiochemical properties, ARPRS was employed to characterize the anisotropic optical properties of as-synthesized 1T′ and 2H-TMD monolayer crystals as the 1T′-TMDs with zigzag chain structures are expected to have angle-dependent Raman intensities. To directly correlate the in-plane anisotropy of Raman modes and the atomic structure of 1T′-MoS₂, HR-TEM characterization (FIGS. 31A and 31B) was performed on the 1T′-MoS₂ monolayer crystal after Raman characterization. The direction along zigzag chains (α-axis) is defined as 0°.

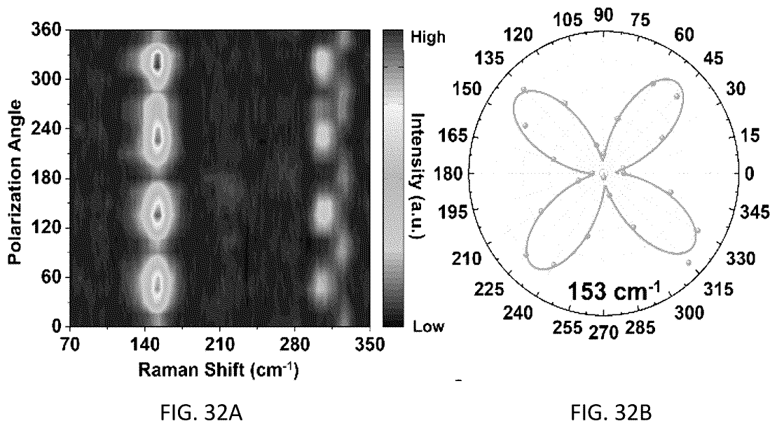

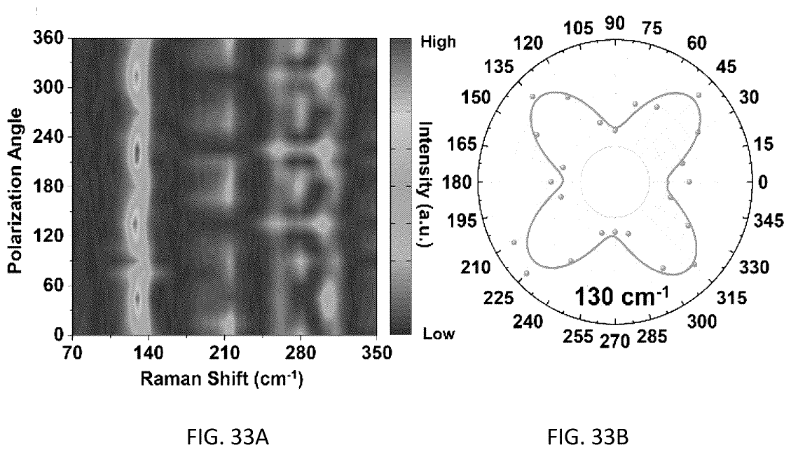

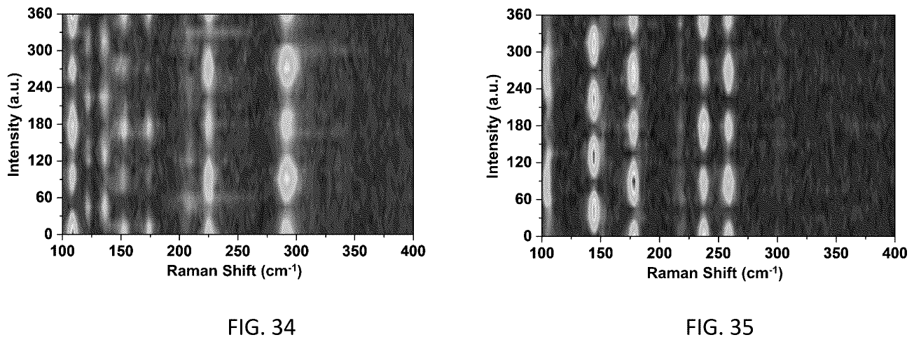

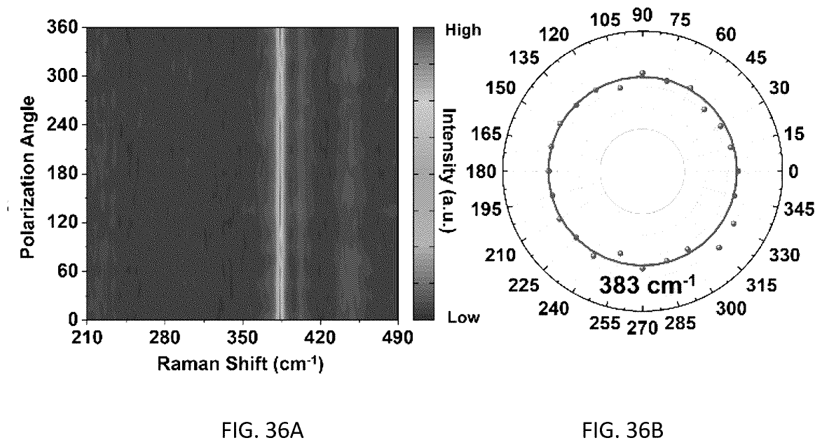

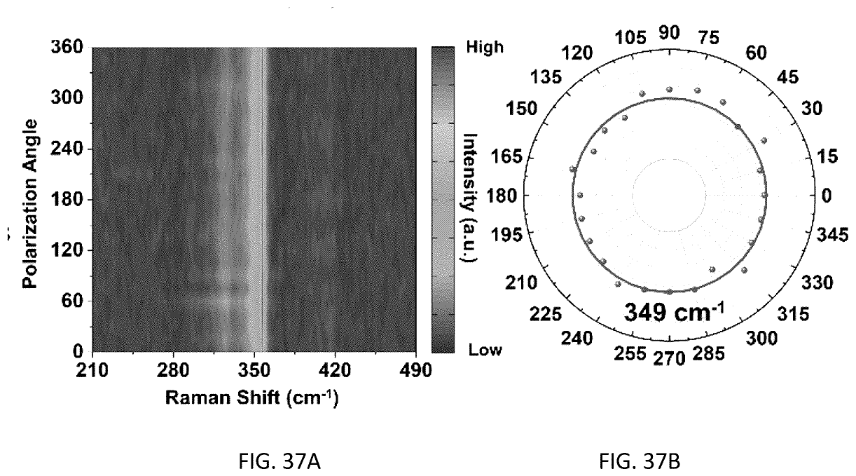

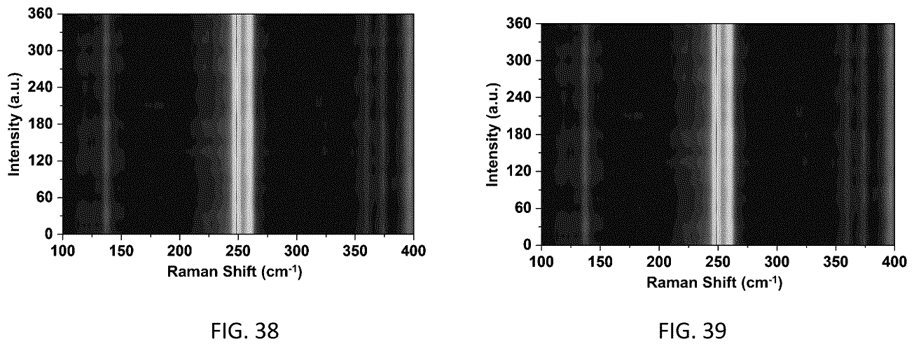

As shown in FIG. 32A, the Raman intensity mapping of 1T′-MoS₂ monolayer crystals displays that the Raman peaks indexed to 1T′-MoS₂ show highly in-plane anisotropic intensities along different directions. As shown in the angle-dependent Raman intensity of the 1T′-MoS₂ monolayers in FIG. 32B, the strongest Raman mode (153 cm⁻¹) of 1T′-MoS₂ monolayers exhibits a fourfold symmetry with four maximum intensities located at ˜45°, ˜135°, ˜225° and ˜315°, indicating a highly anisotropic structural feature of the as-synthesized 1T′-MoS₂ monolayer crystals. Similarly, the Raman intensity mapping and angle-dependent Raman intensities of the as-synthesized 1T′-WS₂ monolayers (FIGS. 33A and 33B), the Raman intensity mapping of the as-synthesized 1T′-MoSe₂ (FIGS. 34) and 1T′-WSe₂ (FIG. 35) demonstrates in-plane anisotropic Raman intensities along different directions. In contrast, the Raman intensity mapping and Raman modes indexed to the as-synthesized 2H—MoS₂ monolayers (FIGS. 36A and 36B) and 2H—WS₂ monolayers (FIGS. 37A and 37B), the Raman intensity mapping of the as-synthesized 2H—MoSe₂ monolayers (FIGS. 38) and 2H—WSe₂ monolayers (FIG. 39) show no anisotropic Raman intensities due to the high-symmetric hexagonal lattice structure of the 2H phase.

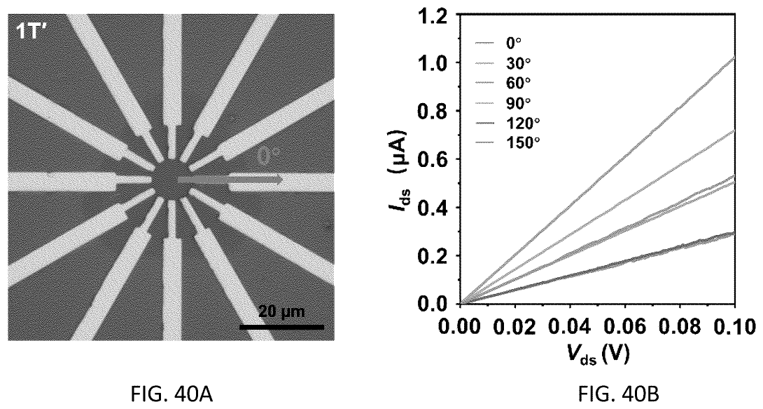

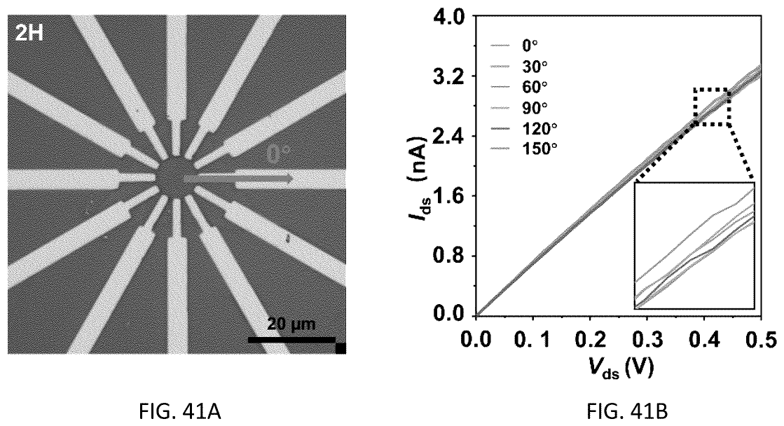

To further investigate the electrical properties of TMD monolayers, typical lithography procedures were employed to fabricate Cr (8 nm)/Au (32 nm) electrodes on the as-synthesized monolayer crystals. Taking 1T′-MoS₂ monolayers as a typical example, a device with 12 evenly spaced electrodes were fabricated on a 1T′-MoS₂ monolayer crystal (FIG. 40A) and the conductance was measured along different crystalline directions (FIG. 40B). Consistent with the results obtained in bulky crystals, the conductance of the 1T′-MoS₂ monolayer crystals is highly angle-dependent and reaches the highest conductance at around 0° (the direction along zigzag chains is defined as 0°) and the same lowest conductance at around 60° and 120°, indicating the as-synthesized 1T′-MoS₂ monolayer crystals are anisotropic conductors. In contrast, the same anisotropic electrical measurement was applied to a device with 12 evenly spaced electrodes fabricated on 2H—MoS₂ monolayer crystals (FIG. 41A), which showed no angle-dependent conductance (FIG. 41B) due to their high-symmetric lattice structure.

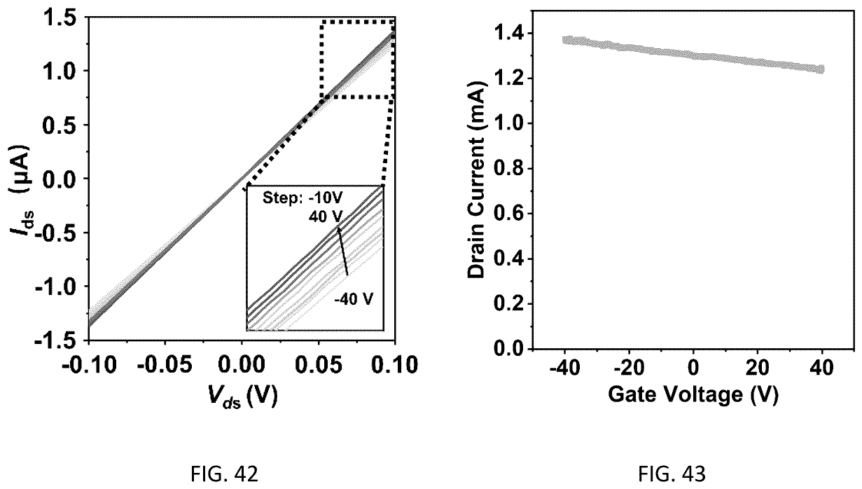

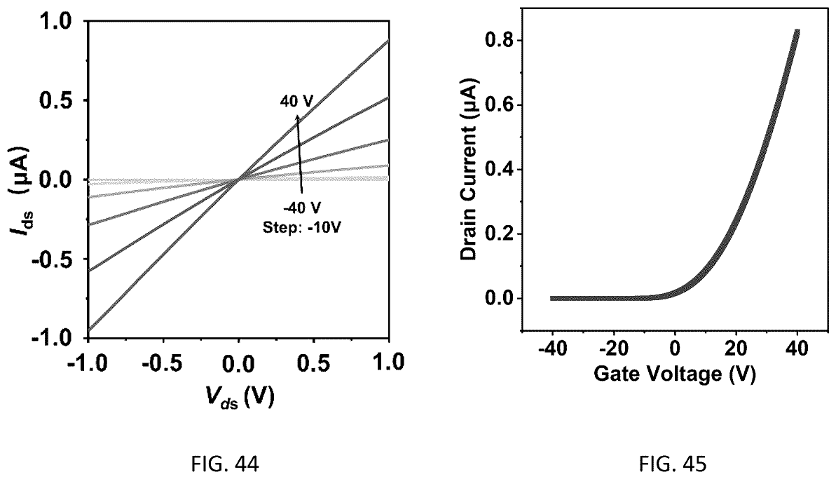

As shown in FIG. 42, the output curves of the 1T′-MoS₂ -based device show a very weak gate response owing to their metallic feature. The transfer curve (FIG. 43) of the 1T′-MoS₂-based device further demonstrates the metallic feature of the as-synthesized 1T′-MoS₂ monolayers. However, both the output curves (FIG. 44) and the transfer curves (FIG. 45) of the device fabricated with 2H—MoS₂ indicate the as-synthesized 2H—MoS₂ monolayer crystals are n-type semiconductors.

### Van der Waals Integrated Rectifier

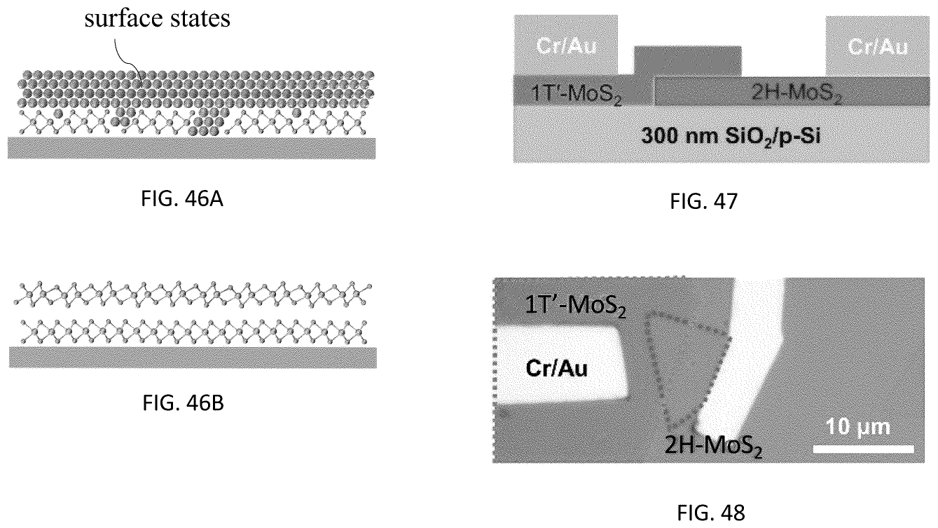

Metal-semiconductor interface always plays a key role in determining the performance of semiconductor devices. As one type of important rectifier beyond the p-n diode, Schottky diodes fabricated with metal-semiconductor have been widely used in modern electronics and optoelectronics due to their excellent on-off switching characteristics. However, Schottky diodes based on conventional evaporated 3D metal-2D semiconductors normally show poor performance owing to the inevitably introduced surface states (FIG. 46A), such as defects, strain, disorder, and diffusion at the metal-semiconductor interfaces during the metal evaporation process, which will lead to severe Fermi-level pinning. The strong Fermi level pinning effect can lead to low Schottky barrier heights and thus bring undesirable rectifying performance. Therefore, Schottky diodes free of surface states (FIG. 46B) are highly demanded for practical applications in future electronics.

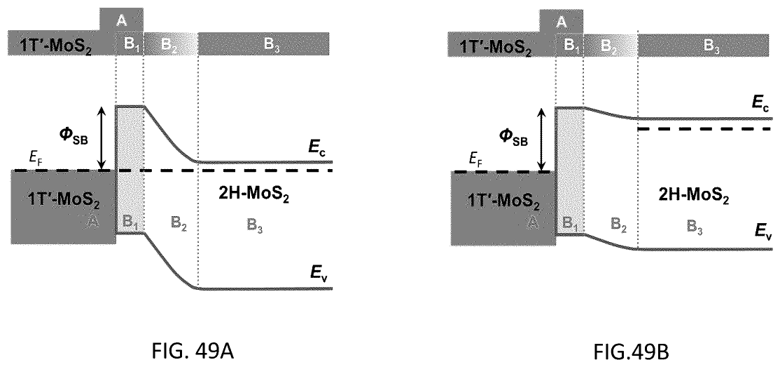

In accordance with another aspect of the present invention, a rectifier employing a 2D homojunction Schottky diode based on a van der Waals integrated 2D metal-2D semiconductor homojunction is provided. FIG. 47 shows an exemplary schematic diagram of the 2D homojunction Schottky diode according to one embodiment of the present invention. Referring to FIG. 47, the 2D homojunction Schottky diode may include a metal part formed of 1T′-TMD (e.g., 1T′-MoS₂) monolayer and a semiconductor part formed of 2H-TMD (e.g., 2H—MoS₂) monolayer. In some embodiments, the 1T′-TMD monolayer may be one of 1T′-MoS₂, 1T′-WS₂, 1T′-MoSe₂ e 1T′-WSe₂ monolayers; and the 2H-TMD monolayer may be one of 2H—MoS₂, 2H—WS₂and 2H—MoSe₂ and 2H—WSe₂ monolayers. FIG. 48 shows an optical image of a 1T′-MoS₂-2H—MoS₂ 2D homojunction Schottky diode based on a van der Waals integrated 1T′-MoS₂-2H—MoS₂ homojunction comprising a metal part formed of 1T′-MoS₂ monolayers and a semiconductor part formed of 2H—MoS₂ monolayers. FIGS. 49A and 49B show band structure diagrams of the van der Waals integrated 1T′-MoS₂-2H—MoS₂ homojunction at zero and forward biased voltages, respectively.

The van der Waals integrated 2D metal-2D semiconductor homojunction can avoid the formation of the surface states and show great potential in creating high performance Schottky diodes with ideal Schottky heights.

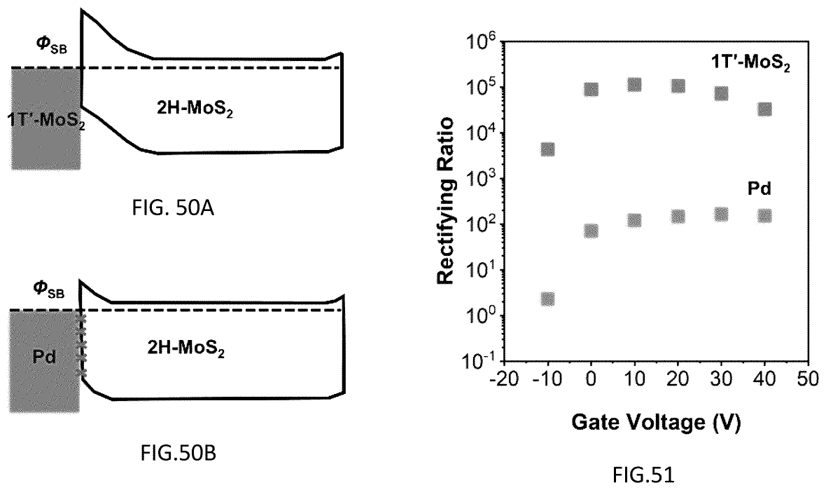

For comparison, a Pd-2H—MoS₂ Schottky diode is build using thermally evaporated high working-function Pd as the metal part and 2H—MoS₂ as the semiconductor part. FIGS. 50A and 50B show schematic illustration of the band structures of the 1T′-MoS₂-2H—MoS₂ 2D homojunction Schottky diode and the Pd-2H—MoS₂ Schottky diode, respectively. Owing to the strong Fermi level pinning effect derived from surface states, the Schottky barrier height in the Pd-2H—MoS₂ diode is significantly reduced in comparison with the 1T′-MoS₂-2H—MoS₂ 2D homojunction Schottky diode. Referring to FIG. 51, the Pd-2H—MoS₂ Schottky diode has rectifying ratios of less than 200 at varied gate voltages whereas the 1T′-MoS₂-2H—MoS₂ 2D homojunction Schottky diode can demonstrate a rectifying ratio of as high as over 10⁵, indicating the great potential of 2D homojunction Schottky diodes to work as high-performance rectifiers for future electronics.

The embodiments may be chosen and described in order to best explain the principles of the invention and its practical application, thereby enabling others skilled in the art to understand the invention for various embodiments and with various modifications that are suited to the particular use contemplated. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations. While the apparatuses disclosed herein have been described with reference to particular structures, shapes, materials, composition of matter and relationships . . . etc., these descriptions and illustrations are not limiting. Modifications may be made to adapt a particular situation to the objective, spirit and scope of the present disclosure. All such modifications are intended to be within the scope of the claims appended hereto.

1. A method for synthesizing a transition metal dichalcogenide (TMD) monolayer crystal, comprising:
mixing a transition metal compound powder and a salt powder to form a precursor;
placing a substrate on top of the precursor;
placing the precursor and the substrate at a center position in a chemical vapour deposition (CVD) furnace;
placing a chalcogen powder at an upstream position relative to the precursor along a gas-flow direction in the CVD furnace;
heating up the CVD furnace to a growth temperature within the heat-up time; and
keeping the CVD furnace at the growth temperature for a growth time under a mixed gas flow of H₂ and Ar.

2. The method of claim 1, wherein
the first temperature ranges for chalcogenides from 250 to 300° C.;
the second temperature ranges for the mixture of salt and transition metal oxides/sulfides from 825 to 875° C.;
the heating time is less than 10 minutes;
the growth time ranges from 2 to 10 minutes;
the heat-up time ranges from 5 to 15 minutes; and
the cooling time ranges is less than 10 minutes.

3. The method of claim 1, wherein the substrate is a fluorophlogopite mica substrate or a sapphire substrate.

4. The method of claim 1, wherein the salt powder is a potassium carbonate (K₂CO₃) powder, a potassium oxalate (K₂C₂O₄) powder, a potassium sulphate (K₂SO₄) powder, a sodium carbonate (Na₂CO₃) powder, a sodium oxalate (Na₂C₂O₄) power or a sodium sulphate (Na₂SO₄) power.

5. The method of claim 1, wherein the substrate is placed exactly on top of the precursor such that the TMD monolayer crystal grown on the substrate has a 1T′ phase.

6. The method of claim 1, wherein the substrate is placed away from the precursor for a diffusion distance ranging from 1 to 3 cm along the gas-flow direction such that the TMD monolayer crystal grown on the substrate has a 2H phase.

7. The method of claim 1, wherein the transition metal compound powder is a molybdenum compound powder and the chalcogen powder is a sulfur powder such that the TMD monolayer crystal grown on the substrate is a molybdenum disulfide monolayer crystal.

8. The method of claim 7, wherein the molybdenum compound powder is a molybdenum trioxide powder.

9. The method of claim 7, wherein the molybdenum compound powder is a molybdenum disulfide powder.

10. The method of claim 1, wherein the transition metal compound powder is a tungsten compound powder and the chalcogen powder is a sulfur powder such that the TMD monolayer crystal grown on the substrate is a tungsten disulfide monolayer crystal.

11. The method of claim 10, wherein the tungsten compound powder is a tungsten trioxide powder.

12. The method of claim 10, wherein the tungsten compound powder is a tungsten disulfide powder.

13. The method of claim 1, wherein the transition metal compound powder is a molybdenum compound powder and the chalcogen powder is a selenium powder such that the TMD monolayer crystal grown on the substrate is a molybdenum diselenide monolayer crystal.

14. The method of claim 13, wherein the molybdenum compound powder is a molybdenum trioxide powder.

15. The method of claim 13, wherein the molybdenum compound powder is a molybdenum diselenide powder.

16. The method of claim 1, wherein the transition metal compound powder is a tungsten compound powder and the chalcogen powder is a selenium powder such that the TMD monolayer crystal grown on the substrate is a tungsten diselenide monolayer crystal.

17. The method of claim 16, wherein the tungsten compound powder is a tungsten trioxide powder.

18. The method of claim 16, wherein the tungsten compound powder is a tungsten diselenide powder.
